(19) United States
(12) Patent Application Publication
(10) Pub. No.: US 2007/0007542 A1
(43) Pub. Date: Jan. 11, 2007

(54) White-Light Emitting Device

(75) Inventor: Shinsuke Fujiwara, Itami-shi, Hyogo (JP)

Correspondence Address: JUDGE & MURAKAMI IP ASSOCIATES, DOJIMIA BUILDING, 7TH FLOOR, 6-8 NISHITEMMA 2-CHOME, KITA-KU, OSAKA-SHI, 530-0047, JP

(73) Assignee: SUMITOMO ELECTRIC INDUSTRIES,LTD., Osaka-shi (JP)

(21) Appl. No.: 11/160,761

(22) Filed: Jul. 7, 2005

(51) Int. Cl. H01L 33/00

(52) U.S. Cl. 257/98

(57) ABSTRACT

High-output white light emitting devices that, being unsusceptible to deterioration despite large drive power, are usable in lighting applications. The light-emitting devices are formed by combining a phosphor component (4) with an LED (2, 3). The phosphorescent component (4) is selected from materials in which the relation between thermal conductivity λ (W/cmK) and absorption coefficient α (1/cm) with respect to light from the LED (2,3) is λα >2, and the substrate (2) utilized for the LED is selected from SiC, GaN or AIN, with LED and phosphorescent component (4) being disposed in contact. Alternatively, the substrate (2) utilized for the LED is sapphire, and the phosphorescent component (4) is disposed in contact with the substrate side of the LED. Allowing heat to be dissipated sufficiently even with input power being 200 W/cm² or more, a configuration of this sort can be used free from the influences of temperature.

### BACKGROUND OF THE INVENTION

1. Field of the Invention

The present invention relates to white-light emitting devices utilizable for lighting, for displays, and in LCD backlight applications.

2. Background Art

A variety of light-emitting diodes that emit white light have been devised in recent years. While white light can be attained by combining light-emitting diodes having the three primary colors-red, green and blue that is-to have devices be low-cost and space-saving, diodes that as single component can emit white are desired. Thus, diodes that emit white light of brightness great enough to be utilizable for lighting, in place of electric bulbs and fluorescent lamps, are being called for.

Against this backdrop, technology that has recently been disclosed renders white light by, as represented in FIGS. 7A and 7B, enveloping the environs of an InGaN-based blue LED with a transparent resin matrix into which YAG phosphor in powdered form has been dispersed. Part of the blue light issuing from the LED is converted into yellow light, and the blue light from the LED and the yellow light from the YAG phosphor synthesize into white light (cf. Photoactive Materials Manual Managing Editorial Board, eds. Photoactive Materials Manual, Optoelectronics Co., June, 1997, p. 457-458). With this technology, as set forth in FIG. 7A, lead 102 and electrode-only lead 103 are anchored within a molding of transparent resin 101, wherein an LED chip 107 is cradled in a recess formed in the fore-end portion of lead 102. Wires 105 and 106 on the LED chip 107 are connected respectively to lead 102 and lead 103. YAG phosphor 110 covering the LED chip 107 fills the recess 104.

Reference is made to FIG. 7B, which is a magnified view of the LED chip 107 and vicinity. The LED is installed in the recess 104 in lead 102, with the LED's substrate 109 located below, and the LED's light-emitting section 108 above. The LED surroundings are infused with the YAG phosphor 110 dispersed throughout the transparent resin filling the recess 104. From the LED light-emitting section 108, the blue light Bemitted heading upward is partially absorbed by the YAG phosphor 110, which emits yellow light Y A portion of the blue light B passing unchanged through the YAG phosphor 110, therefore coincides with the yellow light Y. leading to the issuance of white light.

Another technology, meanwhile, is represented in FIGS. 8A and 8B (c.f. Japanese Unexamined Pat. App. Pub. No. 2000-82845, paragraphs [0019] and [0020], and FIG. 3b). In FIG. 8A, in a transparent resin 111 casting are a lead 112 carrying an LED, and an electrode-only lead 113. The LED carried on the lead 112 is constituted from a ZnSe LED substrate 116, and a ZnCdSe LED light-emitting section 115. Because this LED is electroconductive, for the electrode on one end, the lead 112 is employed directly, with the other end being connected to the lead 113 with a wire 114. The principle of white-light emission with this technology will be explained using FIG. 8B, a magnified view of the LED portion of this device. The LED carried atop the lead 112 is made up of the ZnSe LED substrate 116 and, atop the substrate, the ZnCdSe LED light-emitting section 115. Blue light Bemitted by the LED light-emitting section 115 goes directly into the transparent resin 111 side (omitted from the drawing) of the device, and goes into the LED substrate 116 side; and the rays of blue light B having entered the LED substrate 116 are absorbed into the ZnSe and at the same time are issued as self-excitation rays. The self-excitation rays become yellow light Y or orange light and, permeating the ZnCdSe LED light-emitting section 115 go into the transparent resin 111. The result is that seen from the exterior, the blue light Band the yellow light Y coincide, appearing as white light.

In a further example, in FIG. 9 art having a different structure is disclosed (c.f. Japanese Unexamined Pat. App. Pub. No. 2000-261034, paragraphs [0030] and [0031], and FIG. 1). In this technology, transparent resin 121 covers an electrode-only lead 123 and a lead 122 carrying an LED chip 126, which are fixed to a stem 127. The LED chip 126 and a wire 124 are embedded within the transparent resin 121, together with the leads. A window element 125 is furnished on the upper part of the transparent resin 121, and ZnSe is used for this window element. The LED chip 126, having an InGaN-based light-emitting section, issues blue light. This light permeates the window element 125 and exits to the exterior, while at the same time a portion is absorbed within the window element 125, becoming yellow or orange light and emitted as self-excitation rays. Seen from without, blue light having passed through the window element 125, and self-excitation rays of yellow or orange light within the window element 125 coincide, appearing as white light.

As prior technology, white-light-issuing LEDs to date have existed as discussed above. These white-light emitting devices can be employed in signal/other low-output applications without any problems in particular. In high-output applications in which the devices would serve as substitutes for lamps, however, each technology would require further devising. For example, a problem with YAG phosphor is that due the heat generated by high-power output, the transparency of the material is adversely affected. In the implementations with the ZnSe substrate, the blue-light emitting layer is prone to deteriorating. In the implementations with the ZnSe window element, too much heat emanates from the window element to radiate off. Owing to such problems, rendering the foregoing technology into high-power direct output LEDs presents difficulties.

### SUMMARY OF THE INVENTION

A first aspect of the present invention is a white-light-emitting device, being a phosphorescent component and a light-emitting device (LED) combined, the light-emitting device characterized in that the phosphorescent component is selected from materials in which the relation between the thermal conductivity λ (W/cmK) and the absorption coefficient α (1/cm) with respect to light from the LED is λα>2, and in that the substrate constituting the LED is selected from any of SiC, GaN and AIN, with the LED and phosphorescent component disposed in contact, or else the substrate utilized for the LED is selected from any of SiC, GaN, AIN and sapphire, and the phosphorescent component is disposed in contact with the substrate side of the LED. A configuration of this sort allows the input power that is a load on the LED chip to be employed at a density of 200 W/cm² or more. “Disposed in contact” herein means cohered using an adhesive agent or the like.

For the LED employed, utilizing an InGaN type is especially advisable.

A second aspect of the present invention is a white-light-emitting device, being a phosphorescent component and a light-emitting diode (LED) combined, installed atop a stem, the light-emitting device characterized by a structure in which the LED on the stem is surrounded by a heat-dissipating component along part or all of its periphery, wherein the phosphorescent component is placed in the upper part of the LED, in contact with the heat-dissipating component. Especially preferable is that the thickness t(cm) of the phosphorescent component employed be within the range
\sqrt{S}>t>6S/2000λ
given that the surface area of the phosphorescent component is expressed as S(cm²), and the thermal conductivity as λ (W/cmK). By putting the phosphorescent component thickness in the foregoing range, the heat-dissipating effectiveness—although not a problem at ordinary low-output power—is striking.

Furthermore, adopting a makeup in which the substrate constituting the LED is selected from any of SiC, GaN and AIN, or else the substrate utilized for the LED is selected from any of SiC, GaN, AIN and sapphire, and in which the LED is packaged in a flip-chip form, is preferable in that it makes the configuration one in which heat dissipating capability is taken into consideration.

In the foregoing two aspects of the invention, the principal ingredient of the heat-dissipating component preferably is either aluminum or copper, in that the heat-dissipating properties will be favorable because the thermal conductivity of the material can be made greater. Further, using ZnSₓSe₁₋ₓ(0≦x≦1) to form the employed phosphorescent component is, with the phosphorescent component thus being white-light forming, preferable. And it is advantageous to incorporate within the phosphorescent component one or more of the elements Al, Ga, In, Cl, Br, or I, at 1×10¹⁷ atoms/cm³ or more.

From the following detailed description in conjunction with the accompanying drawings, the foregoing and other objects, features, aspects and advantages of the present invention will become readily apparent to those skilled in the art.

### BRIEF DESCRIPTION OF THE SEVERAL VIEWS OF THE DRAWINGS

FIG. 1 is explanatory diagrams of configurations of the present invention in a first aspect, wherein FIG. 1A is an instance in which the LED is carried in a common way, and FIG. 1B an instance in which the LED is carried as a flip-chip;

FIG. 2 is explanatory diagrams of configurations of the present invention in a second aspect, wherein FIG. 2A is an instance in which the LED is carried in a common way, and FIG. 2B an instance in which the LED is carried as a flip-chip;

FIG. 3 is an example illustrating as an actual embodiment the present invention in the first aspect;

FIG. 4 is an example illustrating as an actual embodiment the present invention in the second aspect;

FIG. 5 plots the relationship between input-power density and chromaticity coordinate in a white-light-emitting device utilizing the first aspect of the present invention;

FIG. 6 plots the relationship between input-power density and chromaticity coordinate in a white-light-emitting device utilizing the second aspect of the present invention;

FIG. 7 is a first example of a white-light-emitting device in the conventional art;

FIG. 8 is a second example of a white-light-emitting device in the conventional art; and

FIG. 9 is a third example of a white-light-emitting device in the conventional art.

### DETAILED DESCRIPTION OF THE INVENTION

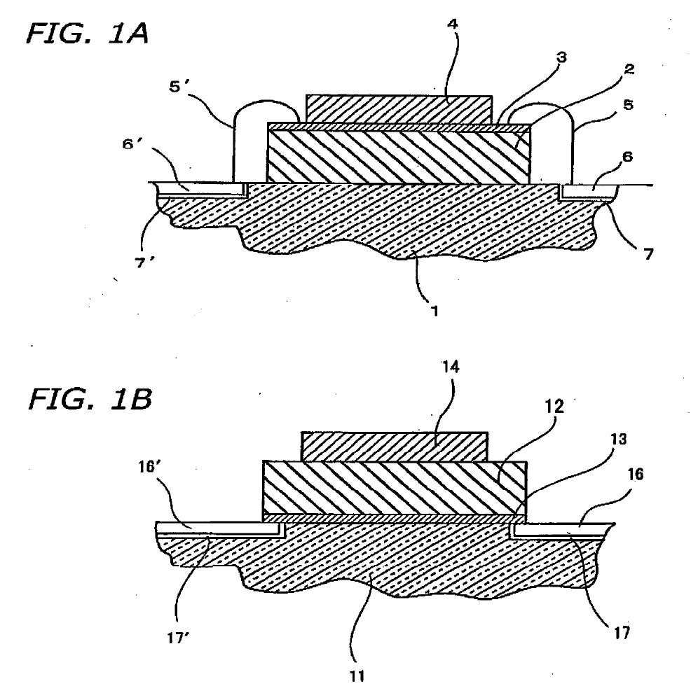

The first aspect of the present invention will be explained using FIGS. 1A and 1B, schematic diagrams. FIG. 1A is a common installation mode, in which the light-emitting section on the LED substrate is put above; FIG. 1B is a form in which the LED is installed as a flip-chip. In FIG. 1A, the LED substrate 2 is joined to a stem 1, and the LED light-emitting section 3 is located atop the substrate 2. In addition, a phosphorescent component 4 is mounted atop the light-emitting section 3. Because the electrodes of the LED are disposed on the side where the LED light-emitting section is, they are connected to external electrodes, through wires 5, 5′ by electrodes 6, 6′ disposed on the stem. The electrodes 6, 6′ are insulated from the stem 1 by insulators 7, 7′. In FIG. 1B in turn, the LED is mounted as a flip-chip on a stem 11. This means that the LED light-emitting section 13 is in contact with the stem 11 and with the LED electrodes, with the LED substrate 12 being located atop the light-emitting section 13. A phosphorescent component 14 is in contact with the further upper part of the LED substrate 12. The LED electrodes are connected directly to electrodes 16, 16′ disposed on the stem 11, thanks to which wires are unnecessary. The electrodes 16, 16′ are insulated from the stem 11 by insulators 17, 17′. In devices possessing the foregoing structure, a distinguishing characteristic in the nature of the materials is that in the phosphorescent components 4 and 14, given that the thermal conductivity is λ (W/cmK) and that the absorption coefficient with respect to the light from the LED is α, αλ>2 is satisfied. Further distinguishing points are that the FIG. 1A implementation has SiC, GaN, or AIN as the material utilized for the LED substrate 2, while the FIG. 1B implementation has SiC, GaN, AIN or sapphire as the material utilized for the LED substrate 12.

The reason for adopting such a structure lies in discharging of the heat generated. Specifically, inasmuch as the thermal conductivity of the transparent resin is low, though the phosphor intermixed into the resin emits heat at the same time it emits light, the surrounding transparent resin cannot be expected to conduct the heat away. On the other hand, concentrating in the transparent resin phosphor whose thermal conductivity is by comparison large can prevent temperature elevation in the resin. Furthermore, putting the heat that is generated there in contact with a material having the capacity to dissipate heat other than heat in the transparent resin makes it possible to prevent temperature elevation also in the phosphor itself.

The configurations of FIG. 1 arise through the significance of the foregoing. Calculations in which this is simplified are detailed below.

Assuming that a white-light-emitting device is manufactured in the FIG. 1A configuration, then putting
w₁: LED heat density (W/cm²),
w₂: phosphorescent component heat density (W/cm²),
T₀: temperature of LED bottom surface (K),
T₁: temperature of LED top surface (K),
T₂: temperature of phosphorescent component top surface (K),
G₁: temperature gradient within LED substrate (K/cm),
G₂: temperature gradient within phosphorescent component (K/cm),
λ₁: thermal conductivity of LED substrate (W/cmK),
λ₂: thermal conductivity of phosphorescent component (W/cmK),
t₁: thickness of LED substrate (cm), and
t₂: thickness phosphorescent component (cm),
   heat-flow balance at equilibrium, expressed with equations, is given as:
   w₁+w₁=λ₁G₁, w₂λ₂G₂; T₁=T₀+t₁G₁; T₂=T₁+t₂G₂.
   Presuming herein that heat emitted from the LED and phosphorescent component is generated in their respective surfaces, in that elevation in temperature tends to be excessive there, there will no problems in terms of safety.

Rearranging the foregoing equations by substituting in equations in which the density of the power fed into the LED is let be w₀ (W/cm²) yields the following:
Δ=T₁−T₀=t₁(w₁+w₂)/λ₁=[(a₁+a₂)t₁/λ₁]w₀;
ΔT₂=T₂−T₀=t₁(w₁+w₂)/λ₁+t₁w₂/λ₂=[(a₁+a₂)t₁/λ₁+a₂t₂/λ₂]w₀.
Herein w₁=a₁w₀, and w₂=a₂w₀, wherein a₁ and a₂ are the heat rate of the LED and the heat rate of the phosphorescent component, respectively.

Utilizing the foregoing equations to estimate a specific temperature elevation is as follows.

An instance in which sapphire is used for the LED substrate 2, InGaN for the LED light-emitting section 3, and ZnSSe (0.5 ZnS composition) for the phosphorescent component 4 will be given as an example. The given specific values were
λ₁ (sapphire): 0.3 W/cmK, and λ₂ (ZnSSe): 0.15 W/cmK;
t₁ (thickness of LED): 0.04 cm, and
t₂ (thickness of phosphorescent component): 0.01 cm;
a₁: 0.7, and a₂: 0.1.
   For a₁, because the external quantum efficiency of InGaN is approximately 30%, the remaining energy was taken to be used up as radiant heat. For a₂, the value was determined by taking it that 10% of the light from InGaN passes through the phosphorescent component, while 20% enters the phosphorescent component, and of that latter proportion, 10% is used up as radiant heat inside the phosphorescent component.

Plugging the foregoing values into the equations set forth above and doing the calculations results in what is set forth in Table I. In this estimation, if the input-power density surpasses 200 W/cm², the LED subjects the phosphorescent component to a 20° C. or greater rise in temperature, creating an unacceptable situation.

It was also understood that inasmuch as temperature differentials originate for the most part in the LED chip, on account of the thermal conductivity of the LED not being large, the effectiveness of employing a phosphorescent component of large thermal conductivity will not be sufficiently manifested. Accordingly, a material whose thermal conductivity is large should be employed for the LED substrate.

What is required of the LED substrate is that it allow the formation of InGaN-based LEDs, and is highly thermally conductive and transparent with respect to the LED-emitted light. SiC, GaN and AIN fit these conditions.

In this respect, Table II is the result of making simulation calculations with the above-noted equations, using these substrate materials. In Table II, the input-power density w₀ is 200 W/cm².

TABLE I

| Input power density | LED surface | Phosphor-material surface |
|---|---|---|
| w₀(W/cm²) | temp. diff. ΔT₁ (° C.) | temp. diff. ΔT₂ (° C.) |
| 100 | 10 | 11 |
| 200 | 20 | 22 |
| 500 | 50 | 55 |
| 1000 | 100 | 110 |

TABLE II

| | Therm. | | |
|---|---|---|---|
| Substrate | conduct. | LED surface | Phos.-mtrl. surface |
| material | λ (W/cmK) | temp. diff. ΔT₁ (° C.) | temp. diff. ΔT₂ (° C.) |
| SiC | 4.9 | 1.3 | 3.3 |
| GaN | 1.3 | 4.9 | 6.9 |
| AlN | 2.9 | 2.2 | 4.2 |
| Sapphire | 0.3 | 20.0 | 22.0 |

According to Table II, with the three types of substrate material listed earlier will be configurations that, with the temperature differential within the LED (ΔT₁) and the temperature differential within the phosphorescent component (ΔT₂−ΔT₁) not bearing a large discrepancy, are usable even under large input-power-density loads. That the temperature gradient can be held to a minimum by using an LED substrate material of large thermal conductivity is as has been discussed above, whereas keeping the temperature differential in the phosphorescent component to a minimum is as follows.

For the phosphorescent component as well, procuring a material of large thermal conductivity will not pose any problems. As far as the material for the phosphorescent component is concerned, being that the objective with the phosphorescent component is to momentarily absorb the monochromatic light from the LED and issue self-excitation rays as light of longer wavelength, the monochromatic light must partially pass through the phosphorescent component; consequently, the element must be transparent with respect to the monochromatic light. This means that the material for the phosphorescent component is selected from within these conditions—that there are limits on the physical properties of the material. Accordingly, conditions under which the material for the phosphorescent component would be used to good effect were singled out. In particular, from the relational formulas employed in the above, a solution can be reached by making it so that a₂t₂/λ₂ will be small. That is, putting into the below—noted formula
a₂t₂/λ₂<(a₁+a₂)t₁/λ₁
the values used in the calculations described earlier, the conditions should be that t₂/λ₂<1. What this means is that the thickness (cm) of the phosphorescent component has a value that is smaller than the thermal conductivity (W/cmK) of the phosphorescent component. In substantial terms, as far as the absorption of heat from the LED-emitted light is concerned, since the heat is almost all absorbed near the surface of the phosphorescent component, letting the LED-light absorption coefficient of the phosphorescent component be α(1/cm), the heat-emitting portion of the element is limited to a width on the order of 2/α(1/cm).

Consequently, the above-noted formula becomes the relation:
αλ>2.
If the phosphorescent component satisfies this relation, it will be usable free of problems arising from temperature elevation.

In a device utilizing sapphire for an LED substrate as described earlier, the fact that the thermal conductivity of the sapphire substrate will be low will lead to problems in transitioning to high output power. In such an implementation, packaging the LED as a flip-chip allows the bulk of the volume of heat emitted to diffuse off on the stem side, making it possible to use the device. Namely, this is an embodiment rendered in the mode of FIG. 1B. Of course, with a substrate of the above-listed SiC, GaN or AIN as well, the LED can be mounted as a flip-chip, forming a structure that, against heat emitted from the light-emitting section, contributes further to mitigating temperature elevation.

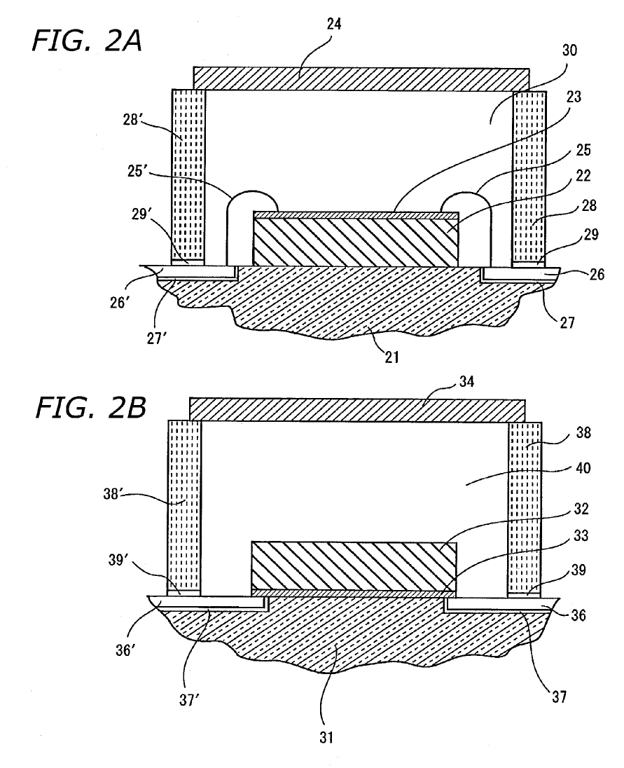

A second aspect of the present invention is illustrated in FIGS. 2A and 2B, schematic diagrams. FIG. 2A is a common installation mode, in which the light-emitting section on the LED substrate is put above; FIG. 2B is a form in which the LED is installed as a flip-chip. In FIG. 2A, the LED substrate 22 is joined to a stem 21, and the LED light-emitting section 23 is located atop the substrate 22. Heat-dissipating elements 28, 28′ are set up surrounding part or all of the LED periphery, and those portions 29, 29′ of the elements that contact the stem as well as the electrodes are electrically insulated. In addition, on their upper part, a phosphorescent component 24 is positioned in contact with the heat-dissipating elements 28, 28′. Because the electrodes of the LED are disposed on the side where the LED light-emitting section is, they are connected by wires 25, 25′ to electrodes 26, 26′ disposed on the stem 21, and furthermore are connected to external electrodes through the electrodes 26, 26′. The electrodes 26, 26′ are insulated from the stem 21 by insulators 27, 27′. Although the space 30 by which the stem 21, heat-dissipating elements 28, 28′, and the phosphorescent component 24 are surrounded may be made a vacuum, ordinarily it is filled with a transparent resin.

In FIG. 2B in turn, the LED is mounted as a flip-chip on a stem 31. This means that the LED light-emitting section 33 is in contact with the stem 31 and with the LED electrodes, with the LED substrate 32 being located atop the light-emitting section 33. Heat-dissipating elements 38, 38′ are set up surrounding part the LED periphery, and those portions 39, 39′ of the elements that contact the stem as well as the electrodes are electrically insulated. A phosphorescent component 34 is positioned in contact with the heat-dissipating elements 38, 38′, a ways above the LED substrate 32. The LED electrodes are connected directly to electrodes 36, 36′ disposed on the stem 31, thanks to which wires are unnecessary. The electrodes 36, 36′ are insulated from the stem 31 by insulators 37, 37′. Although the space 40 by which the stem 31, heat-dissipating elements 38, 38′, and the phosphorescent component 34 are surrounded may be made a vacuum, ordinarily it is filled with a transparent resin.

In short, the FIG. 2 configurations are arrangements in which the LED, being heat-emitting to a high degree, and the phosphorescent component are utilized in a separated state. Accordingly, there being no dissipating via the LED toward the stem, as is otherwise the case with the FIG. 1 configurations, of emitted heat associated with the self-excitation light that the phosphorescent component issues, a heat-dissipating means is adopted by employing separately provided heat-dissipating elements on the periphery. Rendering the LED device in such a form makes possible the dissipating to the stem of heat issued by the LED, and the dissipating, by way of the heat-dissipating elements, into the stem and other components of heat issued by the phosphorescent component.

Herein, likening the phosphorescent component to a discoid and letting W be the amount of heat that phosphorescent component generates, r₂ be the disk outer radius, ΔT be the temperature differential to the circumference from a radius r₁ defined to be from the disk center to the central locus of heat emission, t be the disk thickness, and λ be the thermal conductivity of the phosphorescent component, then the relationship
ΔT=W/λ·In(r₂/r₁)·½πt
is derived.

Furthermore, given that the generated heat is produced throughout the entire disk, the heat may be conceived of as being generated near ½ the disk radius; therefore, substituting r₂=2r₁ into the equation above yields the equation
ΔT=0.11W/λt.

Using dimensional analysis and numerical calculation to compute the heat emitted from the above-defined phosphorescent component yields the relational formula
ΔT₃=0.1W₂/t₂λ₂,
which is a formula that closely approximates the above-stated supposition. Herein, ΔT₃ is the temperature elevation (K) in the central portion of the phosphorescent component. Furthermore, as was set forth in the first aspect of the invention, since the amount of heat W₂ emitted from the phosphorescent component is about 1/10 of the power W₀ input into the LED, the above formula can be expressed as
ΔT₃0.01W₀/t₂λ₂.

As the above-described first aspect of the invention similarly requires, in order for the phosphorescent component not to experience a 20° C. or greater rise in temperature, it is necessary that ΔT₃<20. Thus, the input power should be within the relationship W₀<2000t₂λ₂.

In this case, because the phosphorescent component is surrounded by air, its heat dissipates due to its thermal conductivity. As far as the amount of heat dissipated is concerned, since the heat transfer coefficient of air in its natural transfer of heat by convection currents is on the order of 0.03 W/cm²K, the dissipated-heat quantity Wₐ during a 20° C. elevation in temperature is
Wₐ=0.03×20S=0.6S,
wherein S is the surface area of the phosphorescent component on the side in contact with the air. In this case, because the phosphorescent component's emitted-heat quantity stemming from the LED's input power (W₀) is 0.1 W₀, the dissipated-heat quantity has to be such that Wₐ<0.1 W₀; that is, such that W₀>6S.

It should be noted that in terms of the heat being transmitted during use, the aforesaid dissipated-heat quantity is the quantity of heat dissipated when the phosphorescent component is in a perpendicular state, and thus is less than the practical dissipated-heat quantity. The amount of heat that, not having been taken up by the practical dissipated-heat quantity, remains in the phosphorescent component is absorbed by the heat-dissipating elements through heat-transfer.

From the foregoing two relations, the relation
6S<2000t₂λ₂
is obtained. Because λ₂ is a property of the material, and S is determined by the size of the LED, the relationship must be adjusted by t₂. Thus, it is preferable that
t₂>6S/2000λ₂.
Herein, although there are no particular limitations on t₂, in order to employ the phosphorescent component in plate form, the thickness should be
\sqrt{S}>t₂.
The foregoing conditions hold in a situation in which part of the phosphorescent component is in contact with the heat-dissipating elements. From a manufacturing standpoint, the heat-dissipating elements are installed on the stem on which the LED is mounted, wherein they preferably are installed flanking two sides of the LED, or encompassing the LED along four directions.

Such conditions require that the heat-dissipating elements sufficiently dissipate the heat that the phosphorescent component emits. Accordingly, a material having a greater thermal conductivity than the thermal conductivity of the phosphorescent component may be utilized for the heat-dissipating elements; in particular, utilizing metals of high thermal conductivity, having Cu or Al as the principal component, is preferable.

The foregoing is a description of the situation schematically diagrammed in FIG. 2A, but is equally applicable to the case represented in FIG. 2B, in which the LED is mounted as a flip-chip on the stem. In implementations in which the LED substrate uses a material having sufficient thermal conductivity—specifically, SiC, GaN, or AIN—the configuration in FIG. 2A may be utilized. Implementations in which a material lacking sufficient thermal conductivity—specifically, sapphire—is utilized for the LED substrate require utilizing the configuration in FIG. 2B. In implementations on SiC, GaN, or AIN, although the heat dissipation is better with the device rendered as a flip-chip, with the ordinary way of mounting heat can dissipate adequately.

It should be noted that ZnSSe, ZnS, or ZnSe preferably is used in the phosphorescent component utilized in the first aspect and in the second aspect of the present invention. These materials are denoted together as “ZnSₓSe₁₋ₓ (0≦x≦1).” Other than these materials, ZnCdS can also be utilized.

In addition, it is advantageous to incorporate into the foregoing phosphorescent component atoms that serve as origins for the self-excitation rays; thus atoms of one or more of the elements Al, Ga, In, Cl, Br, or I are incorporated. The wavelength of the self-excitation rays is selectable according to the type and quantity of the atoms incorporated; it is possible for the phosphor to issue red as well as yellow self-excitation rays. Preferably, the amount incorporated should be 1×10¹⁷ atoms/cm³ or more.

### Embodiments

While example embodiments will be set forth in the following, the present invention is not limited to the embodiments below.

### Embodiment 1

ZnSSe crystal (0.5 ZnS composition) grown by the iodine transport method and then heat-treated within a Zn atmosphere at 100° C. was sliced into plates of 200 μm thickness, both sides of which were polished to a mirror-smooth finish. The properties of these ZnSSe phosphor pieces were characterized, wherein the absorption coefficient α with respect to 440-nm wavelength light was 100/cm, and the thermal conductivity λ was 0.15 W/cmK. Accordingly, αλ=15 (W/K). Phosphorescent components 300-μm square were cut from these plates.

Blue LED chips 400-μm square, emitting 440-nm wavelength light, in which were utilized GaN substrates and sapphire substrates having an InGaN active layer on the face, were readied separately.

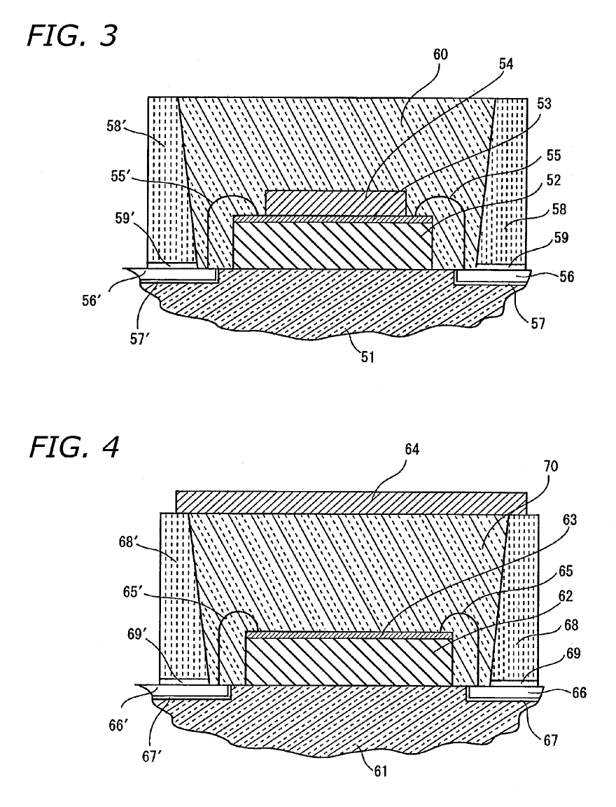

The above-described LEDs and phosphorescent components were utilized to fabricate white-light-emitting devices. The configuration of the devices is illustrated in FIG. 3. Electrodes 56, 56′ preformed with insulators 57, 57′ were arranged on a stem 51 made of aluminum, wherein the LED chip was affixed with an Ag paste onto the stem between the electrodes, with the LED substrate 52 below and the LED light-emitting section 53 above. A ZnSSe phosphorescent component 54 was connected to the top of the chip using a transparent resin. The electrodes on the LED chip were connected with the electrodes 56, 56′ on the aluminum stem 51, using wires 55, 55′ made of gold, after which the periphery of the LED chip and the phosphorescent component was fenced with heat dissipators 58, 58′ made of aluminum, with the portions contacting the stem 51 and electrodes 56, 56′ being insulators 59, 59′. An epoxy-based transparent resin 60 containing a dispersion material constituted from SiC powder was used as a potting to infuse the interior of the enclosure thus produced. At the same time that devices with GaN substrates and sapphire substrates were fabricated, with sapphire substrates, samples in which the LEDs were affixed as flip-chips were also prepared.

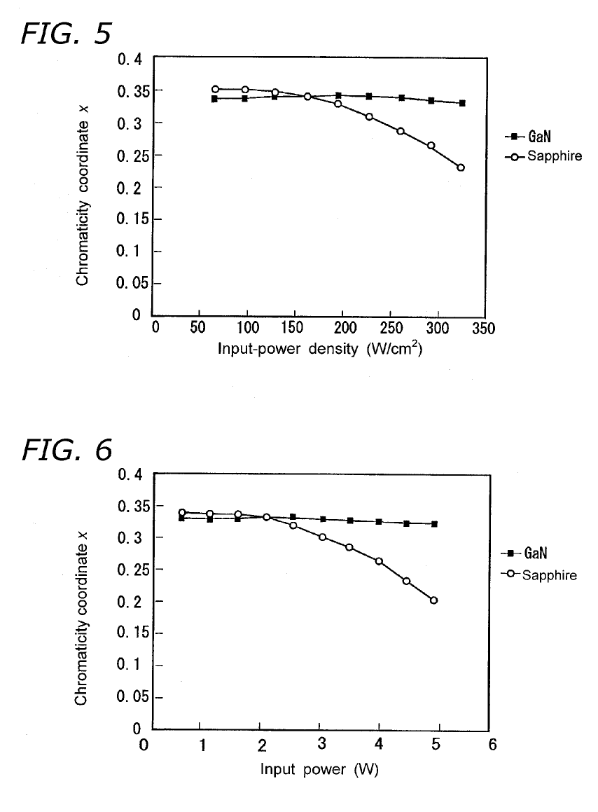

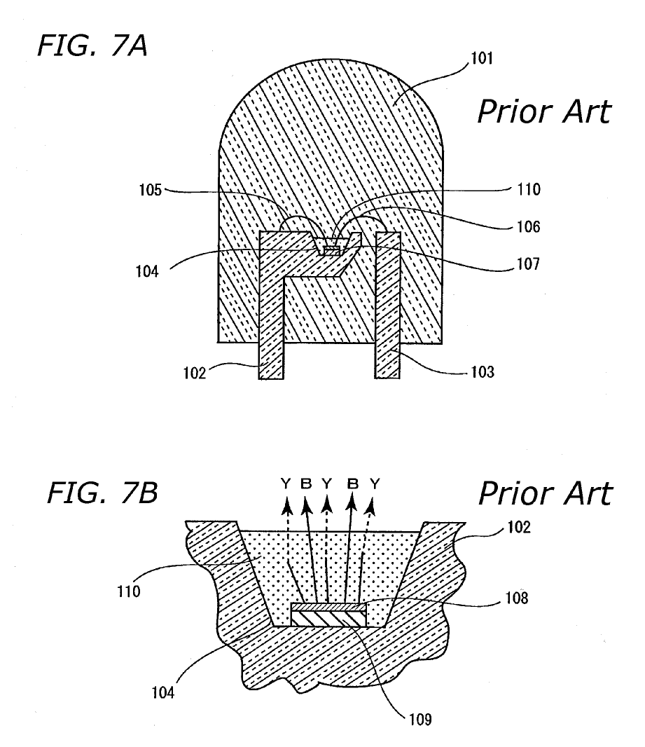

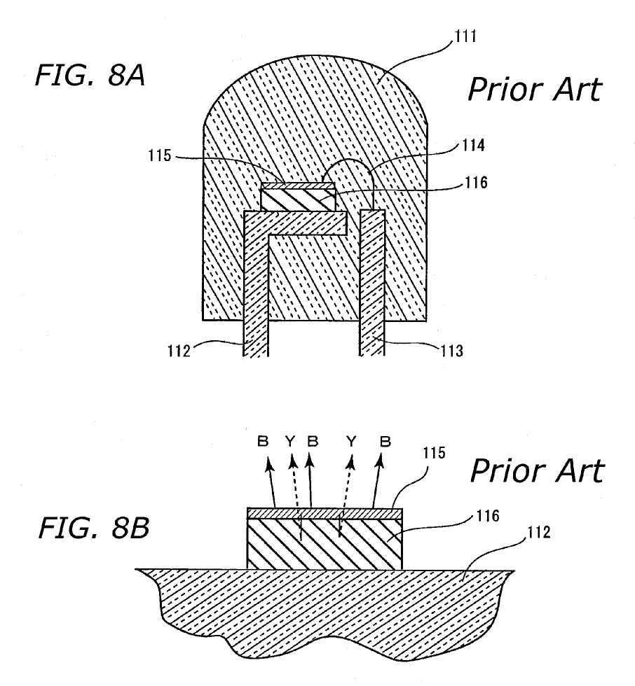

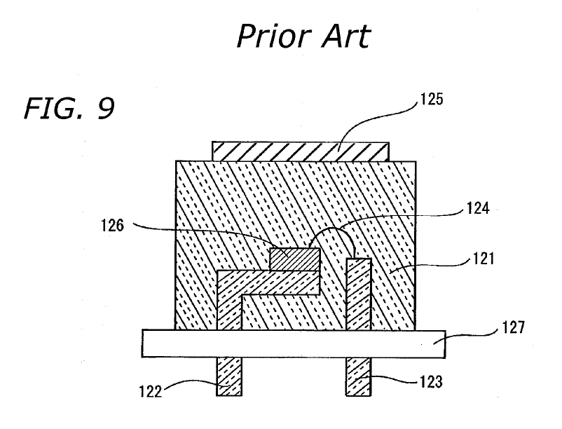

To measure the characteristics of the foregoing three types of white-light-emitting devices, they were connected with external electrodes through which current was passed to cause them to emit light. The distribution of wavelengths emitted above the LEDs was sampled to compute chromaticity coordinates x. The relationship between power density and chromaticity coordinate x, obtained by varying the power fed to the LEDs, is plotted in FIG. 5. In the graph, for LEDs on sapphire, the chromaticity coordinate x begins to change when the input power density surpasses 200 W/cm², but with the LEDs utilizing a GaN substrate, change in the chromaticity coordinate x cannot be seen. Although the measurement was up to a power density of 350 W/cm², white-light-emitting devices defined by the present invention can without problems handle at least an input power density that is again as much as that for LED substrates utilizing sapphire.

It should be noted that although not set forth in FIG. 5, the white-light-emitting devices in which LEDs utilizing a sapphire substrate were affixed as a flip-chip were measured, which yielded much the same data as the FIG. 5 implementation in which GaN-substrate LEDs were utilized.

In Embodiment 1, although heat dissipators encompass the LED periphery, the present invention is viable even if they are not especially used.

### Embodiment 2

The ZnSSe crystal (0.5 ZnS composition) utilized in Embodiment 1 was sliced into plates of 200 μm thickness, both sides of which were polished to a mirror-smooth finish. These were cut into phosphorescent components 3-mm square.

Blue LED chips 1 -mm square, emitting 450-nm wavelength light, in which were utilized GaN substrates and sapphire substrates having an InGaN active layer on the face, were readied separately.

The above-described LED chips and phosphorescent components were utilized to fabricate white-light-emitting devices. The configuration of the devices is illustrated in FIG. 4. Electrodes 66, 66′ were arranged via insulators 67, 67′ beforehand on a stem 61 made of aluminum, wherein the LED chip was mounted in between the electrodes using an Ag paste, with the LED substrate 62 below and the light-emitting section 63 above. After that, the LED electrodes were connected with the electrodes 66, 66′ on the stem, using wires 65, 65′ made of gold. Encompassing the LED chip, heat dissipators 68, 68′ made of aluminum were installed, being insulated 69, 69′ along the stem side. The interior encompassed by the heat dissipators 68, 68′ was infused with an epoxy-based transparent resin 70 as a potting, and atop that the phosphorescent component 64 was set, contacting the heat dissipators 68, 68′, and fixed to the transparent resin 70.

White-light-emitting devices of the configuration described above were fabricated as samples having sapphire substrates, and as samples having GaN substrates. The thermal conductivity A of the phosphor components was the same 0.15 W/cmK as in Embodiment 1, and with S=0.09 cm², therefore t>6/2000·S/λ=0.0018 cm=18 μm.

Current was passed into the white-light-emitting devices, and the emission wavelength distribution above the LEDs was sampled to compute chromaticity coordinates x. The loading input power was variously varied, which yielded the results plotted in FIG. 6. With the LEDs employing sapphire substrates, no change in the chromaticity coordinate x was apparent up to 2 W of input power, but when 2 W was surpassed, change in chromaticity coordinate x could be seen. In contrast, with LEDs defined by the present invention, employing GaN substrates, no change in the chromaticity coordinate x was apparent up to 5 W input power. These results show that white-light-emitting devices defined by the present invention can be used in large-input-power situations, and can be used as high-output white-light-emitting devices.

The present invention affords white-light-emitting devices that are usable not only as signal LEDs that employ white-light-emitting elements, but-withstanding high input power, from which they give rise to high output power-also as LEDs for general lighting applications.

Only selected embodiments have been chosen to illustrate the present invention. To those skilled in the art, however, it will be apparent from the foregoing disclosure that various changes and modifications can be made herein without departing from the scope of the invention as defined in the appended claims. Furthermore, the foregoing description of the embodiments according to the present invention is provided for illustration only, and not for limiting the invention as defined by the appended claims and their equivalents.

What is claimed is:

1. A white-light-emitting device, being a phosphorescent component and an LED combined, the light-emitting device characterized in that:
the phosphorescent component is selected from materials in which the relation between the thermal conductivity λ and the absorption coefficient α with respect to light from the LED is λα>2; and
the substrate constituting the LED is selected from any of SiC, GaN and AIN, with the LED and phosphorescent component disposed in contact.

2. A white-light-emitting device as set forth in claim 1, wherein the phosphor component utilized for the light-emitting device is an InGaN type.

3. A white-light-emitting device as set forth in claim 1, wherein the phosphorescent component is formed from ZnSₓSe₁₋ₓ (0≦x≦1).

4. A white-light-emitting device as set forth in claim 3, wherein at least 1×10¹⁷ atoms/cm³ of any of the elements Al, Ga, In, Cl, Br or I is incorporated within the phosphorescent component.

5. A white-light-emitting device, being a phosphorescent component and an LED combined, the light-emitting device characterized in that:
the phosphorescent component is selected from materials in which the relation between the thermal conductivity λ and the absorption coefficient α with respect to light from the LED is λα>2; and
the substrate utilized for the LED is selected from any of SiC, GaN, AIN and sapphire, and the phosphorescent component is disposed in contact with the substrate side of the LED.

6. A white-light-emitting device as set forth in claim 5, wherein the phosphor component utilized for the light-emitting device is an InGaN type.

7. A white-light-emitting device as set forth in claim 5, wherein the phosphorescent component is formed from ZnSₓSe₁₋ₓ (0≦x≦1).

8. A white-light-emitting device as set forth in claim 7, wherein at least 1×10¹⁷ atoms/cm³ of any of the elements Al, Ga, In, Cl, Br or I is incorporated within the phosphorescent component.

9. A white-light-emitting device, being a phosphorescent component and an LED combined, installed atop a stem, the light-emitting device characterized by a structure in which the LED on the stem is surrounded by a heat-dissipating component along part or all of its periphery, wherein the phosphorescent component is placed in the upper part of the LED, in contact with the heat-dissipating component.

10. A white-light-emitting device as set forth in claim 9, wherein the thickness t of the phosphorescent component is within the range
\sqrt{S}>t>6S/2000λ
wherein the surface area of the phosphorescent component is expressed as S, and the thermal conductivity as λ.

11. A white-light-emitting device as set forth in claim 9, wherein:
the substrate constituting the LED is selected from any of SiC, GaN and AIN, or else the substrate utilized for the LED is sapphire; and
the LED is packaged in a flip-chip form.

12. A white-light-emitting device as set forth in claim 9, wherein the principal ingredient of the heat-dissipating component is either Al or Cu.

13. A white-light-emitting device as set forth in claim 9, wherein the phosphorescent component is formed from ZnSₓSe₁₋ₓ (0≦x≦1).

14. A white-light-emitting device as set forth in claim 13, wherein at least 1×10¹⁷atoms/cm³ of any of the elements Al, Ga, In, Cl, Br or I is incorporated within the phosphorescent component.
